(19) United States
(12) Patent Application Publication
(10) Pub. No.: US 2022/0127752 A1
(43) Pub. Date: Apr. 28, 2022

(54) METHOD FOR MANUFACTURING EPITAXIAL FILM AND EPITAXIAL FILM THEREOF

(71) Applicant: National Cheng Kung University, Tainan City (TW)

(72) Inventors: Jan-Chi Yang, Tainan City (TW); Ping-Chun Wu, Hsinchu City (TW); Chia-Chun Wei, Tainan City (TW)

(73) Assignee: National Cheng Kung University, Tainan City (TW)

(21) Appl. No.: 17/207,961

(22) Filed: Mar. 22, 2021

(30) Foreign Application Priority Data
Oct. 22, 2020 (TW) 109136658

(51) Int. Cl. C30B 33/10; C30B 29/68; C30B 23/02

(52) U.S. Cl. CPC C30B 33/10; C30B 23/02; C30B 29/68

(57) ABSTRACT

The present invention provides a method for manufacturing an epitaxial film and the epitaxial film thereof. The method comprises the steps of: providing a first single crystal substrate and forming a sacrificial layer and a first epitaxial film on the first single crystal substrate; removing the sacrificial layer in order to separate the first epitaxial film from the first single crystal substrate; shifting the first epitaxial film to a second single crystal substrate so as to let the first epitaxial film cover on a partial surface of the second single crystal substrate, wherein the first epitaxial film and the second single crystal substrate are two different crystallographic plane orientations in absolute coordinates; and forming a second epitaxial film on the first epitaxial film and the second single crystal substrate, so as to let the second epitaxial film has at least two crystallographic plane orientations.

### BACKGROUND OF THE INVENTION

### 1. Field of the Invention

The present invention generally relates to a method for manufacturing an epitaxial film and the epitaxial film thereof.

### 2. Description of the Prior Art

Since 2004, graphene was discovered, and thus two-dimensional materials have been a very popular research field in scientific research. From the year of 2017, the Professor Efthimios Kaxiras in Harvard University and his research team stack a double-layer graphene, and under the temperature of 1.1K, rotate the upper graphene an angle, about 1.1°, corresponding to the lower graphene. A result shows that superconductivity exists in the double-layer graphene. Since then, stacking two-dimensional materials with a certain angle is the way to change the electrical structure, and it becomes a very hot research issue, so called Twistronics.

However, how to rotate the angle between stacked two-dimensional materials in order to study resulting material characteristics with different angles is a problem to a person having ordinary skill in the art.

### SUMMARY OF THE INVENTION

The main purpose of the present invention provides a method for manufacturing an epitaxial film, in order to produce the epitaxial film with different crystallographic plane orientations and further research for material characteristics.

The method for manufacturing an epitaxial film comprises the steps of:

(a) providing a first single crystal substrate and forming a sacrificial layer and a first epitaxial film on the first single crystal substrate;
(b) removing the sacrificial layer in order to separate the first epitaxial film from the first single crystal substrate;
(c) shifting the first epitaxial film to a second single crystal substrate so as to let the first epitaxial film cover on a partial surface of the second single crystal substrate, wherein the first epitaxial film and the second single crystal substrate are two different crystallographic plane orientations in absolute coordinates; and
(d) forming a second epitaxial film on the first epitaxial film and the second single crystal substrate, so as to let the second epitaxial film has at least two crystallographic plane orientations.

As aforesaid method, two crystallographic plane indexes of the first single crystal substrate and the second single crystal substrate are the same, and further comprises the step, between step (b) and step (c), of: rotating the first epitaxial film in order to create a relative twist angle be between the crystallographic plane orientation of the first epitaxial film and the crystallographic plane of the second single crystal substrate, alternatively, the two crystallographic plane orientations may not be the same.

As aforesaid method, in step (b), the first epitaxial film separated from the first single crystal substrate floats on a liquid surface.

As aforesaid method, a thickness of the first epitaxial film is between 2 mm and 200 nm.

As aforesaid method, further comprises the step, between step (a) and step (b), of: forming a reinforcement layer on the first epitaxial film. Besides, the method further comprises the step, between step (c) and step (d), of: removing the reinforcement layer.

As aforesaid method, the reinforcement layer is made of polymethylmethacrylate.

As aforesaid method, the materials of the first single crystal substrate and the first epitaxial film are selected from the group consisting of: strontium titanate, silicon, and alumina, and the material of the sacrificial layer is selected from the group consisting of: lanthanum strontium manganese oxide, Sr₃Al₂O₆, yttrium barium copper oxide, and strontium ruthenate.

As aforesaid method, in step (a), forming the sacrificial layer and the first epitaxial film on the first single crystal substrate is by means of pulsed laser deposition (PLD) or other epitaxy technologies.

As aforesaid method, in step (d), forming the second epitaxial film on the first epitaxial film and the second single crystal substrate is by means of a pulsed laser deposition (PLD) or other epitaxy technologies.

As aforesaid method, step (c) further comprises the steps of:

(c1) shifting the first epitaxial film to the second single crystal substrate; and;
(c2) forming a plurality of openings on the first epitaxial film.

As aforesaid method, after step (d), further comprises the step of using a chemical-mechanical polishing to flatten the surface of the second epitaxial film.

The other purpose of the present invention provides an epitaxial film with different crystallographic plane orientations, more particularly to that of using aforesaid method for manufacturing. In step (d), the second epitaxial film is with different crystallographic plane orientations.

As a conclusion, the crystallographic plane orientation of the first epitaxial film can be varied by researcher, therefore at least two epitaxy areas with different crystallographic plane orientations can be formed on the second epitaxial film. Via studying the boundaries of the epitaxy areas, a lot of new material characteristics can be found.

Other and further features, advantages, and benefits of the invention will become apparent in the following description taken in conjunction with the following drawings. It is to be understood that the foregoing general description and following detailed description are exemplary and explanatory but are not to be restrictive of the invention.

The accompanying drawings are incorporated in and constitute a part of this application and, together with the description, serve to explain the principles of the invention in general terms. Like numerals refer to like parts throughout the disclosure.

### BRIEF DESCRIPTION OF THE DRAWINGS

The objects, spirits, and advantages of the preferred embodiments of the present invention will be readily understood by the accompanying drawings and detailed descriptions, wherein:

FIG. 1 illustrates a schematic view of a preferred embodiment of an epitaxial film of the present invention;

FIG. 2A to FIG. 2C illustrates a plurality of surface states of different embodiments of the epitaxial film of the present invention;

FIG. 3A to FIG. 3H illustrate schematic views of an embodiment of the method for manufacturing the epitaxial film of the present invention;

FIG. 4 illustrates a flowchart of the method for manufacturing the epitaxial film of the present invention;

FIG. 5 illustrates a schematic 3-D view of a first epitaxial film and a second single crystal substrate;

FIG. 6 illustrates a surface state of a boundary of the two epitaxial films and a height difference presented by NanoScope Analysis;

FIG. 7 illustrates a schematic 3-D view of a first epitaxial film, a third epitaxial film and a second single crystal substrate; and

FIG. 8A and FIG. 8B illustrate an embodiment of a lithography process according to the method for manufacturing an epitaxial film of the present invention.

### DETAILED DESCRIPTION OF THE INVENTION

Following preferred embodiments and figures will be described in detail so as to achieve aforesaid objects.

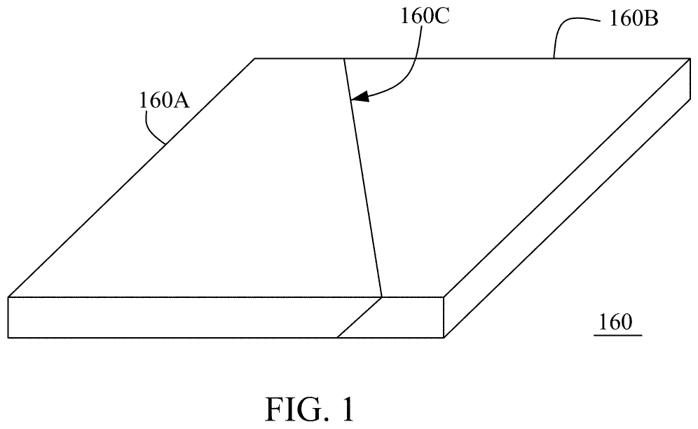

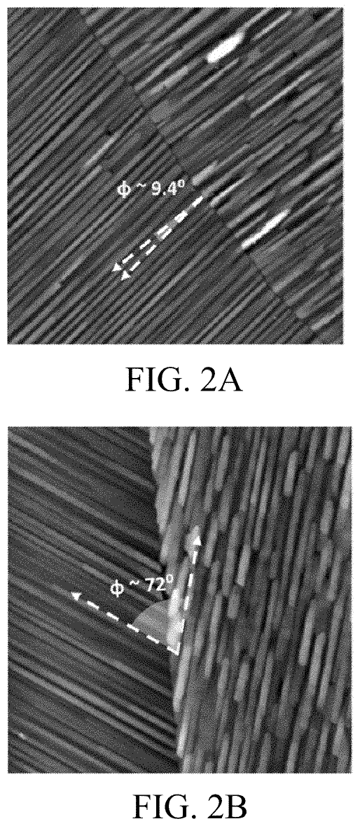

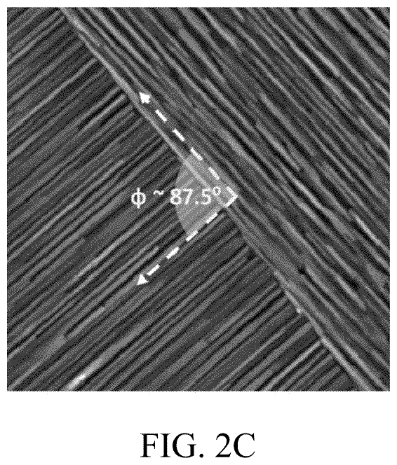

With reference to FIG. 1, which illustrates a schematic view of a preferred embodiment of an epitaxial film of the present invention. As shown in FIG. 1, an epitaxial film 160 is made of epitaxial processes. For the embodiment, the epitaxial film 160 has two epitaxy areas that are a first epitaxy area 160A and a second epitaxy area 160B. For the absolute coordinates, a crystallographic plane orientation of the first epitaxy area 160A is different than a crystallographic plane orientation of the second epitaxy area 160B. Thus, a transition area 160c is spread at the boundary of the first epitaxy area 160A and the second epitaxy area 160B. Please refer to FIG. 2A to FIG. 2C simultaneously, which illustrate a plurality of surface states of different embodiments of the epitaxial film of the present invention. FIG. 2A to FIG. 2C are photographed by atomic force microscope, and the epitaxial film is made of Bismuth Ferrite (BiFeO₃, BFO). As shown in the figures, the crystallographic plane orientation at the left area of the epitaxial film is totally different than the right areas, so as to obviously form the boundary at a central area of the epitaxial film. The transition area at the boundary may generate the effect of stacking two-dimensional materials. Therefore, some new material properties may be found through the transition areas. Hereinafter, the method for manufacturing the epitaxial film 160 will be described in detail.

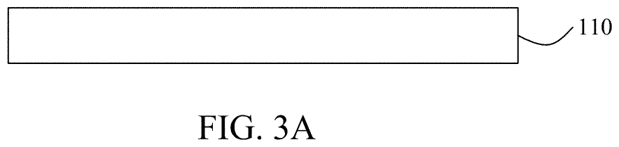

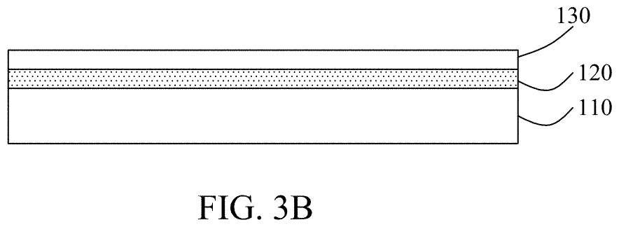

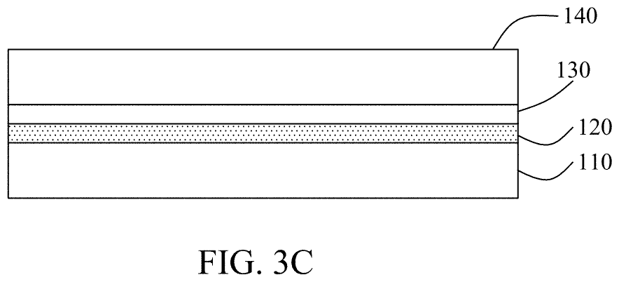

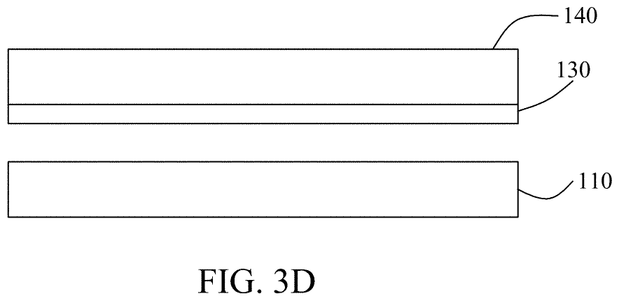

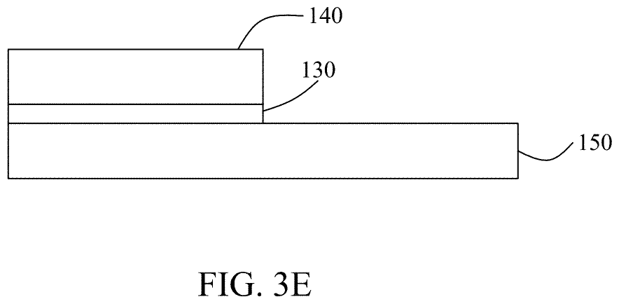

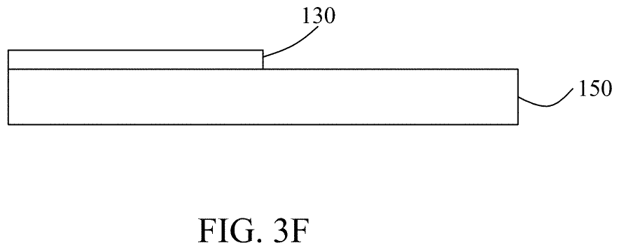

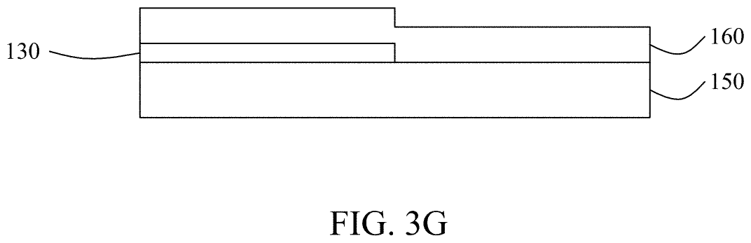

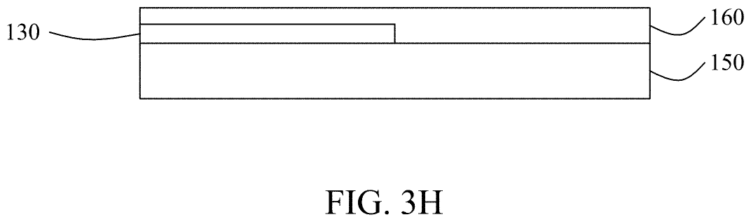

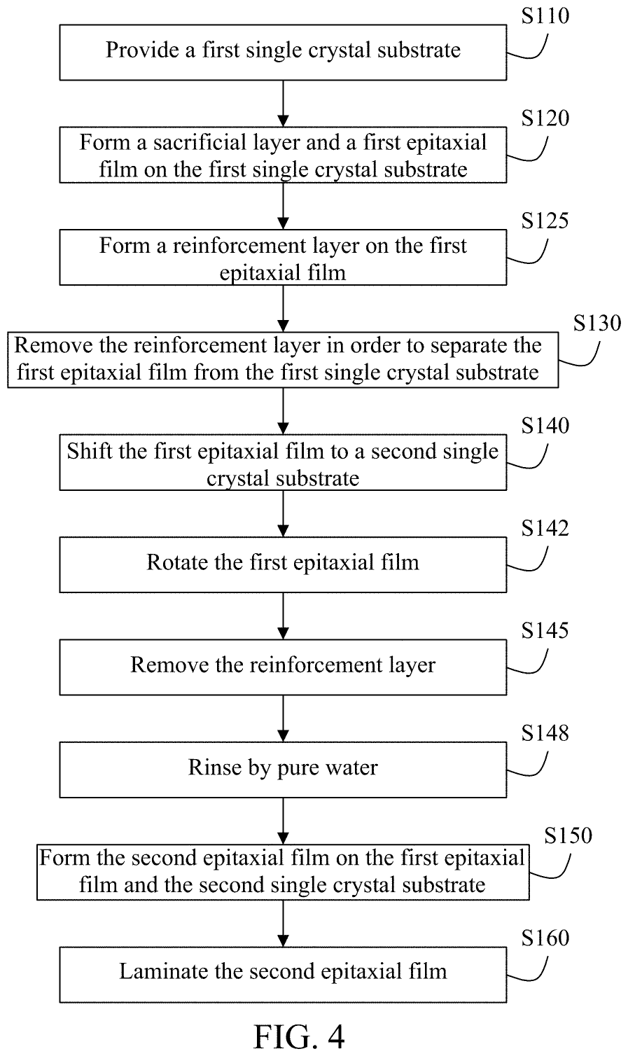

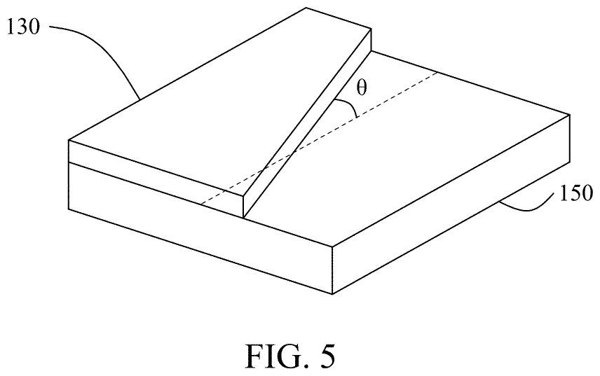

FIG. 3A to FIG. 3H illustrate schematic views of an embodiment of the method for manufacturing the epitaxial film of the present invention. FIG. 4 illustrates a flowchart of the method for manufacturing the epitaxial film of the present invention. Hereinafter, both FIG. 3A to FIG. 3H and FIG. 4 will be described and referred. As it can be seen, FIG. 3A to FIG. 3H are only schematic views without realistic dimensions. Referring to FIG. 3A, a step S110 is to provide a first single crystal substrate 110, which material can be selected from the group consisting of strontium titanate, silicon, and alumina (Al₂O₃). For the embodiment, the first single crystal substrate 110 is made by strontium titanate, and a crystallographic plane index of the first single crystal substrate 110 is (110) as an example. Referring to FIG. 3B, a step S120 is to form a sacrificial layer 120 and a first epitaxial film 130 on the first single crystal substrate 100. For the embodiment, the technology of

Pulsed Laser Deposition is applied, and other technologies may be suitable for person having ordinary skill in the art—. For examples, metal-organic chemical vapor deposition (MOCVD), molecular beam epitaxy (MBE), liquid phase epitaxy (LPE), vapor phase epitaxy (VPE), selective epitaxial growth (SEG), etc.

The material of the sacrificial layer 120 can be selected from the group consisting of: lanthanum strontium manganese oxide (LSMO), Sr₃Al₂O₆, yttrium barium copper oxide (YBCO), and strontium ruthenate (SrRuO₃). For the embodiment, the sacrificial layer 120 is made of yttrium barium copper oxide. On the other hand, the material of the first epitaxial film 130 is selected from the group consisting of: strontium titanate, silicon, and alumina, and is strontium titanate as of the embodiment. Since the sacrificial layer 120 and the first epitaxial film 130 grow up on the first single crystal substrate 10, the crystallographic plane indexes of the sacrificial layer 120 and the first epitaxial film 130 are the same as the first single crystal substrate 110's for the embodiment. More, a thickness of the first epitaxial film is between 2 mm and 200 nm.

With reference to FIG. 3C, a step S125 is to form a reinforcement layer 140 on the first epitaxial film 130. The material of the reinforcement layer 140 is polymethylmethacrylate, and the reinforcement layer 140 forms on the first epitaxial film 130 by means of spin coating. In addition, other materials should be made for the reinforcement layer 140 as well. The function to the reinforcement layer 140 is to provide a mechanic support for what the first epitaxial film 130 continuously moves on.

Please refer to FIG. 3D, a step S130 is to remove the reinforcement layer 120 in order to separate the first epitaxial film 130 from the first single crystal substrate 110. In the embodiment, an etching solution, e.g. hydrochloric acid (HCl) or potassium iodide (KI), etches the lanthanum strontium manganese oxide in order to get rid of the reinforcement layer 120. After that, the first epitaxial film 130 floats over the etching solution (not shown in figure). Referring to FIG. 3E, a step S140 is to shift the first epitaxial film 130 to a second single crystal substrate 150 so as to let the first epitaxial film 130 cover on a partial surface of the second single crystal substrate 150. One of the embodiments, the crystallographic plane index of the second single crystal substrate 150 is the same as the first single crystal substrate 110's.

Consequently, the crystallographic plane indexes of the second single crystal substrate 150 and the first epitaxial film 130 are the same. Please refer to FIG. 5, which illustrates a schematic 3-D view of the first epitaxial film 130 and the second single crystal substrate 150. To precisely demonstrate the relative positions of the first epitaxial film 130 and the second single crystal substrate 150, FIG. 5 does not appear the reinforcement layer 140. For the first epitaxial film 130 and the second single crystal substrate 150 having different crystallographic plane orientations, a step S142 shall be executed before shifting the first epitaxial film 130 to the second single crystal substrate 150. That is, a two-dimensional material positioning system (not shown in figure) rotates the first epitaxial film 130 in order to make an angle θ between the two crystallographic plane orientations of the first epitaxial film 130 and the second single crystal substrate 150, wherein the angle θ is 9.4° as an example.

According to FIG. 3F, a step S145 is to remove the reinforcement layer 140. For the embodiment, since the reinforcement layer 140 is made of polymethylmethacrylate, and then is removed by acetone. After removing the reinforcement layer 140, a step S148 is to rinse by pure water in order to make no residue left on the first epitaxial film 130. As shown in FIG. 3G, a step S150 is to form the second epitaxial film 160 on the first epitaxial film 130 and the second single crystal substrate 150. In the embodiment, a technology of pulsed laser deposition (PLD) is the way to form the second epitaxial film 160 on the first epitaxial film 130 and the second single crystal substrate 150. At this time, please refer to FIG. 1, the second epitaxial film 160 is the same as the epitaxial film 160, and they are given the same number. Since the first epitaxy area 160A and the second epitaxy area 160B proceed epitaxial growth on the first epitaxial film 130 and the second single crystal substrate 150 respectively, the crystallographic plane orientation of the first epitaxy area 160A is the same as the first epitaxial film 130's, and the crystallographic plane orientation of the second epitaxy area 160B's is the same as the second single crystal substrate 150's.

In above processes, there is a height difference in thickness between the first epitaxial film 130 and the second single crystal substrate 150 due to the thickness of the first epitaxial film 130. Hence, as shown in FIG. 3H, a step S160 is executed. That is, the height difference is eliminated by means of chemical-mechanical polishing. Frankly speaking, the surface of the second epitaxial film 160 is laminated.

According to above descriptions, although the two crystallographic plane indexes of the first epitaxial film 130 and the second single crystal substrate 150 are the same, to proceed epitaxial growth still forms the second epitaxial film 160 by way of rotating the first epitaxial film 130 an angle on the second single crystal substrate 150. Due to the angle being variable, the researcher is able to observe different properties in different angles. As an example, with reference to that of FIG. 2A to FIG. 2C, the angle between the two crystallographic plane orientations of the left area and the right area of the epitaxial film is 9.4°, as shown in FIG. 2A; on the other hand, the angle is 72° in FIG. 2B and is 87.5° in FIG. 2C.

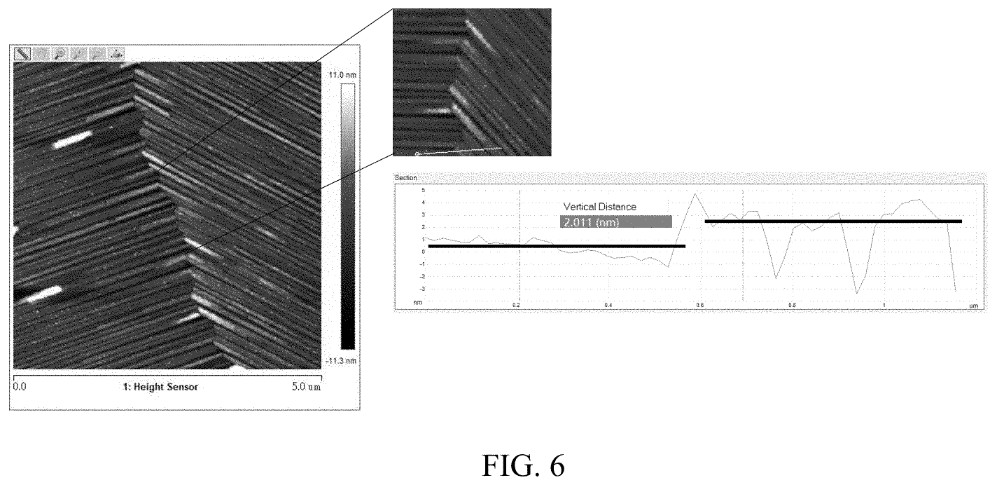

According the experimental results, even though the thickness of the first epitaxial film 130 is only 2 nm, the crystallographic plane orientation of the first epitaxy area 160A, above the first epitaxial film 130, is equal to the crystallographic plane orientation of the first epitaxial film 130. As shown in FIG. 6, in which the right-hand side shows a surface state of the boundary of the two epitaxial films, and the left-hand side illustrates that two different crystallographic plane orientations are spread at the two sides of the boundary. A scanning probe microscopy (SPM) is to measure the surface characteristics of the epitaxial film, so as to obtain the height difference. In FIG. 6, the tool “section” of the NanoScope Analysis chooses a target section as an area with a white line in FIG. 6 in order to the surface state of the target section, that is, the ups and downs on the right-hand side of FIG. 6. The NanoScope Analysis may produce the average height difference is about 2 nm. The second epitaxial film 160 is simultaneously deposited on both the first epitaxial film 130 and the second single crystal substrate 150, so that the crystallographic plane orientation of the first epitaxy area 160A, above the first epitaxial film 130, is decided based on only 2 nm-thickness of the first epitaxial film 130.

According to that of the two crystallographic plane indexes of the first epitaxial film 130 and the second single crystal substrate 150 being equal to each other, a step S142 shall be executed, that is to rotate the first epitaxial film 130. However, if the crystallographic plane index of the first single crystal substrate 110, for example (111), is different than the second single crystal substrate 150's, the two crystallographic plane indexes of the first epitaxial film 130 and the second single crystal substrate 150 may not be the same. Obviously, the step S142 is not necessary, and the two crystallographic plane orientations of the first epitaxial film 130 and the second single crystal substrate 150 are not the same as well.

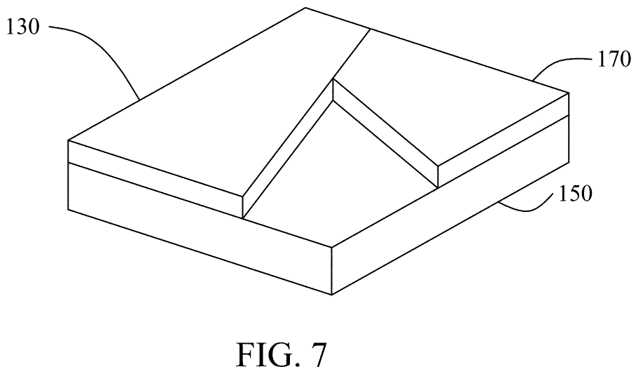

An important issue is as following. The processes from FIG. 3A to FIG. 3G may produce an epitaxial film with three different crystallographic plane orientations. Referring to FIG. 7, not only the first epitaxial film 130 is disposed on the second single crystal substrate 150, but also a third epitaxial film 170 does. The crystallographic plane orientation of the third epitaxial film 170 is different than the second single crystal substrate 150's and the first epitaxial film 130's, so as to obtain the epitaxial film having three different crystallographic plane orientations. As it can be seen, disposing a plurality of epitaxial films with different crystallographic plane orientations on different sections of the second single crystal substrate 150 may definitely deposit the epitaxial films with different crystallographic plane orientations.

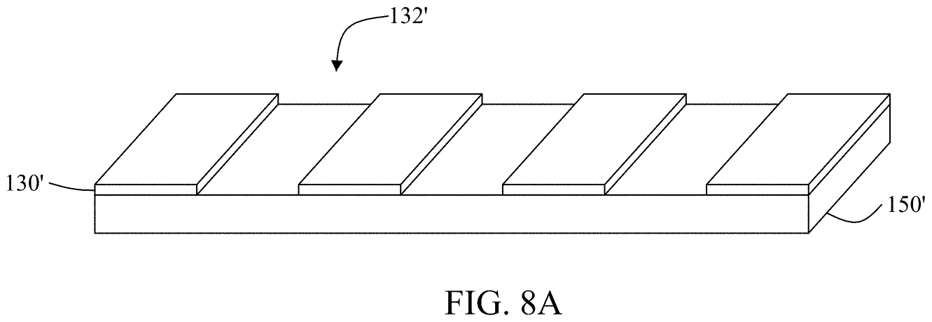

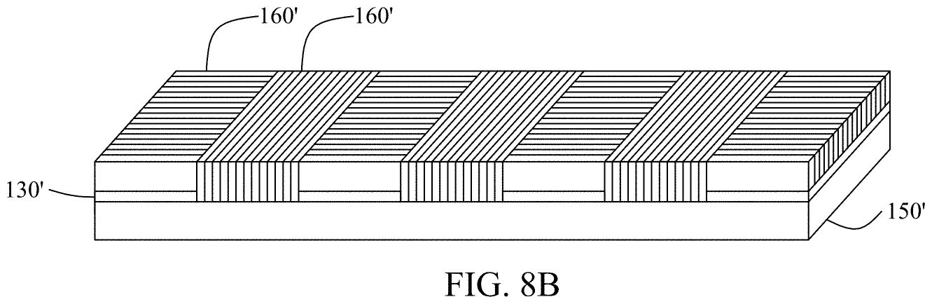

Besides, the processes from FIG. 3A to FIG. 3G may cooperate with a lithography process to produce a more complicate epitaxial film. As shown in FIG. 8, a first epitaxial film 130′ disposed on a second single crystal substrate 150′ has a plurality of openings 132′ that is made by the lithography process, such as yellow light lithography or electron beam lithography process. Continuously, a second epitaxial film 160′ is formed on the first epitaxial film 130′ and the second single crystal substrate 150′, as shown in FIG. 8B. In such a way, those second epitaxial films 160′ with different crystallographic plane orientations are crossed and laminated. That is, forming the openings 132′ with different figures is to grow the epitaxial films 160′ with different shapes.

Although the invention has been disclosed and illustrated with reference to particular embodiments, the principles involved are susceptible for use in numerous other embodiments that will be apparent to persons skilled in the art. This invention is, therefore, to be limited only as indicated by the scope of the appended claims

What is claimed is:

1. A method for manufacturing an epitaxial film comprising the steps of:
(a) providing a first single crystal substrate and forming a sacrificial layer and a first epitaxial film on the first single crystal substrate;
(b) removing the sacrificial layer in order to separate the first epitaxial film from the first single crystal substrate;
(c) shifting the first epitaxial film to a second single crystal substrate so as to let the first epitaxial film cover on a partial surface of the second single crystal substrate, wherein the first epitaxial film and the second single crystal substrate are two different crystallographic plane orientations in absolute coordinates; and
(d) forming a second epitaxial film on the first epitaxial film and the second single crystal substrate, so as to let the second epitaxial film has at least two crystallographic plane orientations.

2. The method for manufacturing the epitaxial film according to claim 1, wherein two crystallographic plane indexes of the first single crystal substrate and the second single crystal substrate are the same, further comprising the step, between step (b) and step (c), of:
rotating the first epitaxial film in order to create a relative twist angle be between the crystallographic plane orientation of the first epitaxial film and the crystallographic plane of the second single crystal substrate.

3. The method for manufacturing the epitaxial film according to claim 1, wherein the step (b) further comprises the steps of:
(b1) removing the sacrificial layer by means of an etching solution, in order to separate the first epitaxial film from the first single crystal substrate; and
(b2) floating the first epitaxial film on a liquid surface of the etching solution.

4. The method for manufacturing the epitaxial film according to claim 1, wherein a thickness of the first epitaxial film is between 2 mm and 200 nm.

5. The method for manufacturing the epitaxial film according to claim 1 further comprising the step, between step (a) and step (b), of: forming a reinforcement layer on the first epitaxial film, and the step, between step (c) and step (d), of: removing the reinforcement layer.

6. The method for manufacturing the epitaxial film according to claim 5, wherein the reinforcement layer is made of polymethylmethacrylate.

7. The method for manufacturing the epitaxial film according to claim 1, wherein the materials of the first single crystal substrate and the first epitaxial film are selected from the group consisting of: strontium titanate, silicon, and alumina, and the material of the sacrificial layer is selected from the group consisting of: lanthanum strontium manganese oxide, Sr₃Al₂O₆, yttrium barium copper oxide, and strontium ruthenate.

8. The method for manufacturing the epitaxial film according to claim 1, wherein the first single crystal substrate and the first epitaxial film are made of strontium titanate, and the sacrificial layer is made of lanthanum strontium manganese oxide.

9. The method for manufacturing the epitaxial film according to claim 8, wherein the second epitaxial film is made of bismuth ferrite.

10. The method for manufacturing the epitaxial film according to claim 7, wherein the second epitaxial film is made of bismuth ferrite.

11. The method for manufacturing the epitaxial film according to claim 1, wherein step (a) of forming the sacrificial layer and the first epitaxial film on the first single crystal substrate is by means of a pulsed laser deposition (PLD).

12. The method for manufacturing the epitaxial film according to claim 1, wherein step (d) of forming the second epitaxial film on the first epitaxial film and the second single crystal substrate is by means of a pulsed laser deposition (PLD).

13. The method for manufacturing the epitaxial film according to claim 1, wherein the step (c) further comprises the steps of:
(c1) shifting the first epitaxial film to the second single crystal substrate; and
(c2) forming a plurality of openings on the first epitaxial film.

14. An epitaxial film with different crystallographic plane orientations made by the steps of:
(a) providing a first single crystal substrate and forming a sacrificial layer and a first epitaxial film on the first single crystal substrate;
(b) removing the sacrificial layer in order to separate the first epitaxial film from the first single crystal substrate;
(c) shifting the first epitaxial film to a second single crystal substrate so as to let the first epitaxial film cover on a partial surface of the second single crystal substrate, wherein the first epitaxial film and the second single crystal substrate are two different crystallographic plane orientations in absolute coordinates; and
(d) forming a second epitaxial film on the first epitaxial film and the second single crystal substrate, so as to let the second epitaxial film has at least two crystallographic plane orientations;
wherein the second epitaxial film of step (d) has different crystallographic plane orientations.

15. The epitaxial film according to claim 14, wherein a thickness of the first epitaxial film is between 2 mm and 200 nm.

16. The epitaxial film according to claim 14, wherein the reinforcement layer is made of polymethylmethacrylate.

17. The epitaxial film according to claim 14, wherein the materials of the first single crystal substrate and the first epitaxial film are selected from the group consisting of: strontium titanate, silicon, and alumina, and the material of the sacrificial layer is selected from the group consisting of: lanthanum strontium manganese oxide, Sr₃Al₂O₆, yttrium barium copper oxide, and strontium ruthenate.

18. The epitaxial film according to claim 14, wherein the first single crystal substrate and the first epitaxial film are made of strontium titanate, and the sacrificial layer is made of lanthanum strontium manganese oxide.

19. The epitaxial film according to claim 18, wherein the second epitaxial film is made of bismuth ferrite.

20. The epitaxial film according to claim 17, wherein the second epitaxial film is made of bismuth ferrite.

21. The epitaxial film according to claim 14, wherein the step (c) further comprises the steps of:
(c1) shifting the first epitaxial film to the second single crystal substrate; and
(c2) forming a plurality of openings on the first epitaxial film.
